(19) United States
(12) Patent Application Publication
(10) Pub. No.: US 2026/0222706 A1
(43) Pub. Date: Jul. 30, 2026

(54) Texture imaging using angle-sensitive pixels

(71) Applicant: The Board of Trustees of the Leland Stanford Junior University, Stanford, CA (US)

(72) Inventors: Nayeun Lee, Campbell, CA (US); Mark L. Brongersma, Menlo Park, CA (US); Jiho Hong, Sunnyvale, CA (US)

(21) Appl. No.: 19/158,203

(22) PCT Filed: Feb. 23, 2024
(86) PCT No.: PCT/US2024/017147

§ 371 Date: Aug. 20, 2025

Related U.S. Application Data
(60) Provisional application No. 63/447,841, filed on Feb. 23, 2023.

(51) Int. Cl. H04N 25/77

(52) U.S. Cl. CPC H04N 25/77

(57) ABSTRACT

Improved angle-sensitive imaging is provided by integrating metasurfaces or the like with pixel elements of a detector array. Two or more classes of pixel elements are employed having overlapping (but distinct) angular responses. This allows the per-pixel extraction of coordinates of a texture space (analogous to color space) to efficiently display texture information. For example, texture information can be displayed in a false color or false gray scale scheme.

### FIELD OF THE INVENTION

This work relates to texture-sensitive optical imaging.

### BACKGROUND

Humans perceive surface textures from their appearance that depends on the (spatially-varying) angular distribution of reflected light from a surface. Thus, quantitative characterization of such information is a fundamental problem in various applications, especially in artificial intelligence (computer vision and scene understanding) and computer graphics (modeling and rendering). However, conventional cameras are not capable of capturing this angular information of the light from a scene as their image sensor displays similar sensitivities to the incoming light rays from different directions and compresses them into a two-dimensional image plane.

Two approaches which have been considered in the art for providing angle-sensitive imaging are angle-sensitive pixels (ASPs) and light-field cameras.

Previous research on angle-sensitive pixels achieves this function by placing two sets of gratings spaced apart by a few microns above CMOS image sensors to sort the light depending on its incident angle. However, this leads to relatively bulky ASPs because of the large pixel area required, and therefore remains mostly in the research stage.

Light-field cameras (or plenoptic cameras) is another approach which also leverages the concept of sensing propagating direction of light to extract depth information from the scene. In most light-field cameras, the cost to capture the directional information is a severe sacrifice of the resolution. This is because an image sensor of fixed resolution must be divided into the number of viewing angles.

Accordingly, it would be an advance in the art to provide improved angle-sensitive imaging.

### SUMMARY

This work provides a new type of imaging technology that can discern surface textures by utilizing nanostructured image pixels with distinct and engineered angular responses. As their angular responses can be engineered by differently nanopatterning conventional pixels, a variety of surface textures can be effectively distinguished even with a minimal set of the angle-sensitive pixels. We refer to such angle-sensitive pixels as “metapixels”.

Using a nanophotonic approach, we incorporate an angular sensitivity function to a conventional image sensor at the single pixel level and in a compact fashion. Since image sensors are typically made of high-index semiconductors (e.g. silicon), an array of high-index nanostructures can be created by nanopatterning the top-most semiconductor surfaces. Due to their optical resonances (e.g. Mie resonances), these nanostructures can be designed to locally manipulate the surface scattering pattern of incoming light in a controlled fashion. This allows each nanostructured pixel to display its desired angular sensitivity, separately from its neighbors, without the need of additional filters or lenses. By choosing nanostructure designs with the same height, an array of distinctly angle-sensitive pixels can be created simultaneously in a CMOS-compatible process.

In one example, analogous to human color vision, we use three types of nanostructured pixels (left (L), center (C), right (R)) to effectively differentiate surface textures. The human visual system can distinguish a large number of different colors (spectral distributions) using three types of photoreceptors (S, M, L) that each offer distinct spectral sensitivity curves across the visible range. Similarly, we construct three types of angle-sensitive pixels in which each type becomes mostly sensitive to the light from different directions (left, center and right). Through nanostructure design, their angular sensitivity curves can be engineered across a broad angular range of interest, enabling the perception of a wide range of surface textures. Here, we demonstrate that it is possible to achieve overall high efficiencies in all types of pixels and leverage their small angle-dependent differences to retrieve texture information.

To visualize the texture information, we again use the mapping method used in colorimetry. As the S, M, L values are linearly transformed to tristimulus value X, Y, Z in CIE XYZ color space, the absorption differences in L, C, R pixels are linearly transformed to construct X,Y,Z values in XYZ texture space. Using this method, we can estimate the appearance (how specular or diffuse) or surface curvature (directionality of incoming light) by looking at the colors in the reconstructed texture image. The acquired texture information can be useful for material (texture) sensing, depth sensing, and rendering 3-dimensional objects.

Applications include, but are not limited to: Machine vision cameras, security cameras, virtual reality (VR) and mixed reality (MR) headsets, light-field cameras, LIDAR (light detection and ranging) cameras, and conventional cameras.

Significant advantages are provided relative to more conventional approaches:

This work provides an angle-sensitive CMOS image sensor. Therefore, compared with conventional image sensors, it is superior in terms of capturing additional information, i.e., the angular distribution of light. While the conventional image sensor compresses this information in a two-dimensional image plane, our pixels extract such information and generate texture images by employing a small difference in absorption of neighboring pixels. Also, we can optimize the pixels to have a high average efficiency so that the angle-sensitive pixel can also act as conventional pixels.

Phase detection autofocus (PDAF), especially approaches that employ dual/quad pixel sensor, shares similarity as it decomposes the scene into two images seen from left and right (four images seen from up/down/left/right for quad pixel sensor). While the purpose of PDAF is to improve autofocusing, the nanostructured pixels of this work retrieve information on angular distribution of light with three types of pixels as a basis.

Our approach captures angular distribution of reflectance and use the information to roughly estimate surface appearances. The silicon nanoresonators placed directly on top of pixels support optical resonances, which are designed to offer distinctive angle-sensitive functions to pixels. This nanophotonic approach is beneficial as the desired optical function can be easily tuned by tailoring geometries of nanostructures. Since the nanostructures adds angle-sensitive function to the conventional image sensor, there is no need to provide space for additional microlens arrays or gratings. The reconstruction of texture image undergoes our image processing method that assign textures to colors.

At the same time, these nanostructures for compact angle-sensitive pixels can be optimized to perform similarly compared to conventional CMOS image sensors. Therefore, our approach does not sacrifice pixel resolution of the captured image, thereby facilitating the realization of texture imaging.

The preceding description has concentrated on an example with a 3-element texture basis. This basis could have 2 elements or 4 or more elements. Another variation is for pixels to be configured to match specific textures analogous to the use of matched filters in signal processing. In further variations, the two degrees of angular freedom in light scattered from a surface are accounted for (e.g., instead of a 3-element left-center-right basis, we could have a 5-element basis including center, northwest, northeast, southeast, southwest).

### BRIEF DESCRIPTION OF THE DRAWINGS

FIGS. 1A-C schematically show several embodiments of the invention.

FIG. 2A shows exemplary angular distributions of light emitted from an illuminated object.

FIG. 2B schematically shows operation of a conventional camera.

FIG. 2C schematically shows operation of a light-field camera.

FIG. 2D schematically shows operation of an embodiment of the invention.

FIG. 3A schematically shows optical imaging, an angle dependent illumination at the detector array, and exemplary left, center, and right responses of pixels of the detector array FIG. 3B schematically shows a 3-parameter texture space, analogous to a 3-parameter color space.

FIG. 3C shows an exemplary fabricated metapixel.

FIG. 3D shows a metasurface configuration for a “center” pixel.

FIG. 3E shows a metasurface configuration for a “left” metapixel.

FIG. 3F shows measured angle-dependent sensitivity for left, center and right metapixels.

FIG. 4A-E show exemplary imaging results from a detector array having angle-selective metapixels, including texture imaging.

### DETAILED DESCRIPTION

Section A describes general principles relating to embodiments of the invention. Section B describes theoretical and experimental work relating to exemplary embodiments of the invention.

### A) General Principles

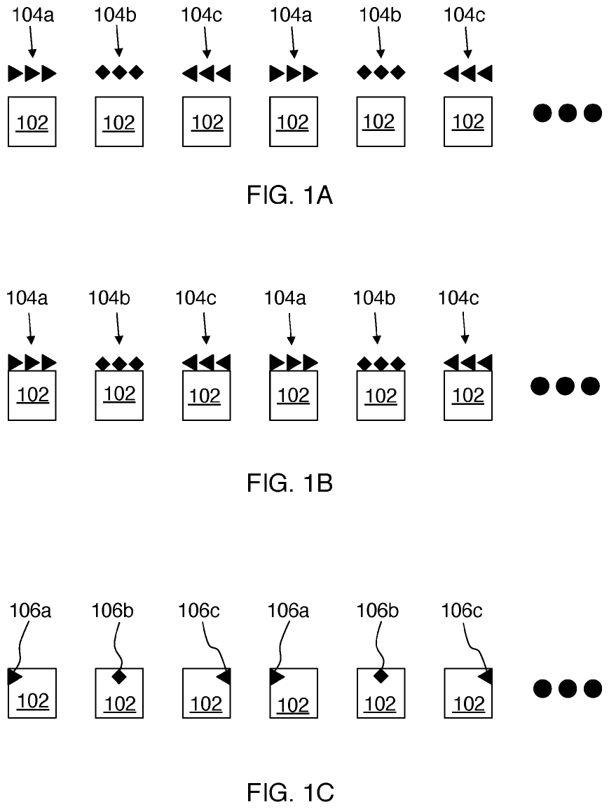

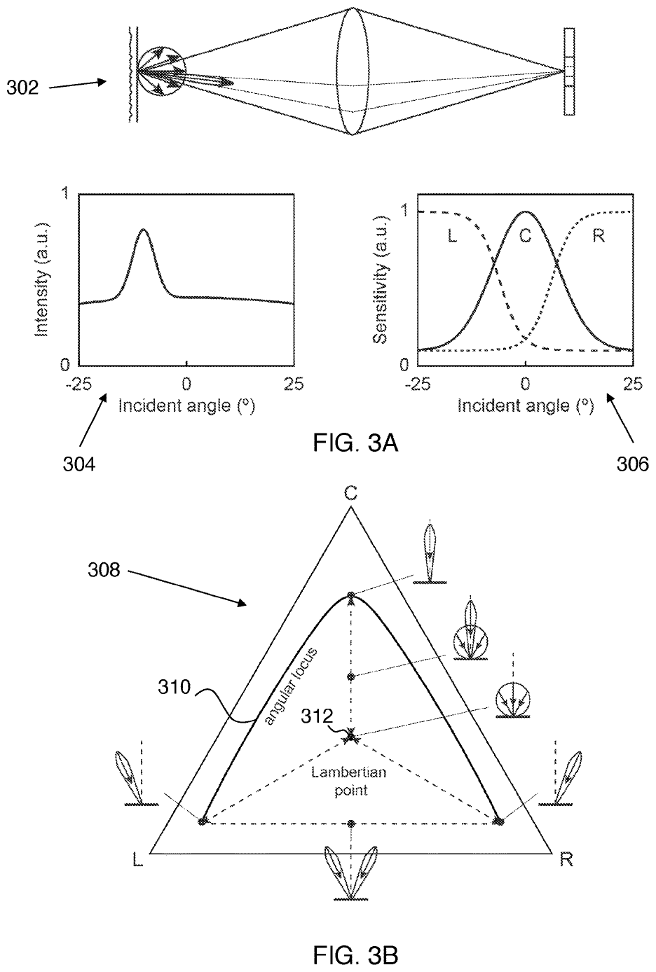

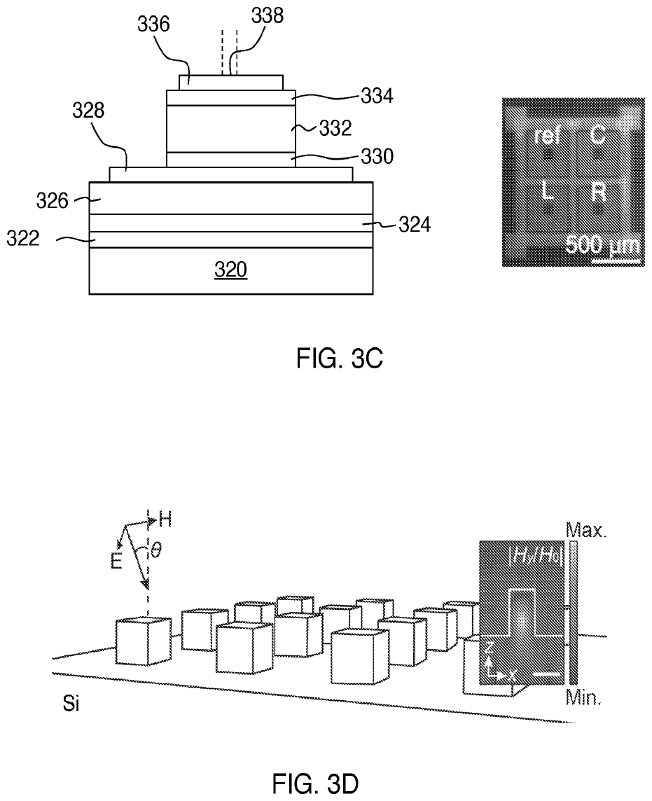

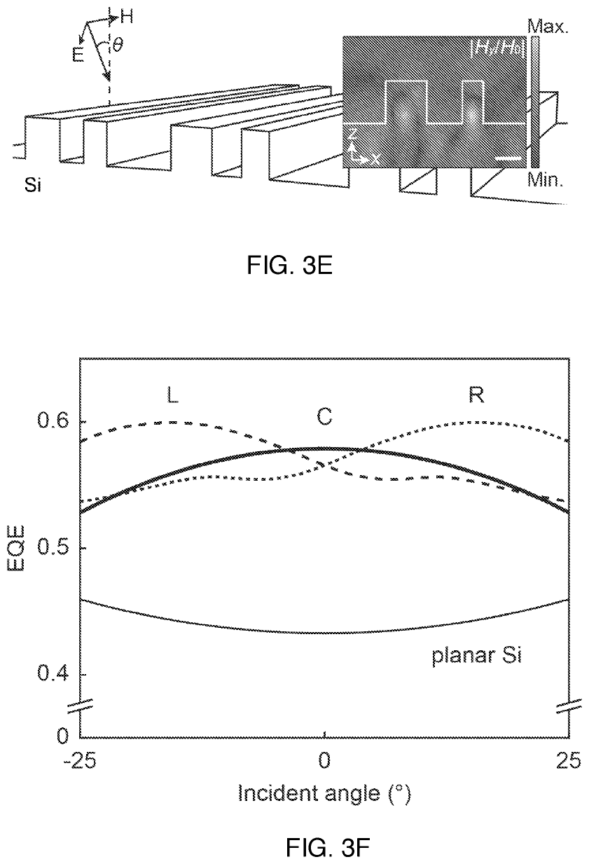

FIGS. 1A-C shows exemplary embodiments of the invention. The example of FIG. 1A includes an array of pixel detection elements, each pixel detection element including an optical detector 102 and an optical nanostructure (104a, 104b, or 104c) disposed on or over the optical detector and configured such that the pixel detection element is angle-sensitive. The pixel detection elements include two or more classes of pixel detection elements, each class of pixel detection elements including two or more pixel detection elements. Here these classes are referenced as 104a, 104b, 104c and are schematically shown with different symbols (right arrowhead, diamond, left arrowhead, respectively). Pixel detection elements in the same class have the same angle-sensitive response. Pixel detection elements in different classes have different angle-sensitive responses. The different angle-sensitive responses have response vs. angle curves that overlap (e.g., 306 on FIG. 3A). The main benefit of such overlap is that there are no “dead zones” where differences in incident intensity vs. angle have no effect on the output texture responses.

Here an “optical nanostructure” is a structure including one or more sub-wavelength features. One example of an optical nanostructure is an optical metasurface having two or more sub-wavelength features disposed on a common substrate. Such a common substrate can be planar or curved, and can be flexible or rigid.

In the example of FIG. 1A, the optical nanostructures are optical metasurfaces, and these metasurfaces are disposed over the optical detectors. Such metasurfaces can also be integrated with the optical detector, as in the example of FIG. 1B and the examples of section B. Another alternative is shown on FIG. 1C. Here the optical nanostructures include one or more nano-scale features (e.g., 106a, 106b, 106c) of the optical detector. The difference between the examples of FIGS. 1B and 1C is that the example of FIG. 1C does not necessarily form a metasurface for each pixel element. In other words, it may be possible to obtain sufficient angular dependence with per-pixel features that don't form a metasurface.

Any number (>=2) of classes of pixel detection elements can be employed. Some specific examples follow. In cases where three classes are used, a false coloring having three primary colors can be used to display texture as color. Three classes of pixel detection elements can be configured to distinguish three different 1-D incidences.

Four classes of pixel detection elements can be configured to distinguish four different 2-D incidences (e.g., left, right, up, down, or northeast, northwest, southeast, southwest). Three or more classes of pixel detection elements can be configured to distinguish three or more different 1-D or 2-D incidences.

At least one of the different angle-sensitive responses can be configured to act as a matched filter for a texture of interest. One simple example of this would be quality testing of blazed diffraction gratings, where configuring an angle-sensitive pixel to match the blaze direction of a diffraction grating could improve testing of diffraction gratings. Security holograms that are made with different patches of gratings are another possible application of this idea.

Practice of the invention does not depend critically on the lateral arrangement of the different classes of angle-sensitive pixel elements. In cases where three classes are employed, it is expected that various arrangements of three kinds of pixel as known from color displays would all be applicable to this case. More generally, it is expected that dense repetition of a unit cell including one of each class of angle-sensitive pixel would lead to suitable lateral arrangements of the different classes of angle-sensitive pixel elements.

### B) Examples

Light carries plentiful information on a scene via its multiple degrees of freedom. By resolving light with distinct physical properties, cameras or imaging systems are enabled to obtain specific information on an optical scene. This has laid the foundation for a variety of techniques in photography and optical imaging. Conventional cameras sense the intensity and spectral content of light at each spatial location, capturing color images similarly to the human visual system. Such cameras have been used in conjunction with a set of external optical elements for imaging based on other intrinsic properties of light, for instance, phase, polarization, and light-field imaging. Over the last decades, there has been great interest in achieving these imaging functions in a compact fashion, especially with a single camera, to bring new capabilities to various fields including computer vision and extended reality. This evolution has been spurred by recent advances in metasurfaces that facilitate on-demand control over light waves beyond conventional optics.

Surface texture is another visual modality based on the scattering pattern of light from a surface, complementary to others such as color and shape. Since it contributes to the realistic appearance of an object, this visual attribute has played a crucial role in a range of fields including computer graphics. Traditionally, the texture of an optical surface is analyzed by measuring a four-dimensional angular distribution function, called the bidirectional reflectance distribution function (BRDF), which provides a full description of the scattering characteristics. However, its accurate measurement typically involves time-consuming iteration over both illumination and detection directions on a bulky gonioreflectometer, hindering the use of surface texture in emerging applications such as real-time scene understanding. Here, we present a new type of nanostructured image pixel, called metapixels, enabling compact and efficient texture imaging of an optical scene. Due to their designer nanostructures, metapixels can display distinct angular response functions at the pixel level without the need of external optics. Inspired by the human color vision, we show triangular texture vision with three different types of angle-sensitive metapixels that produce angular basis elements for effective perception of texture.

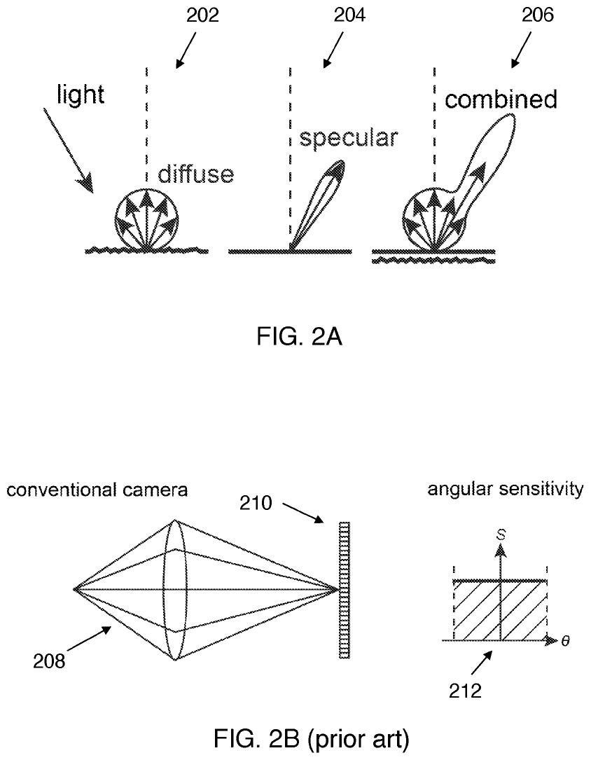

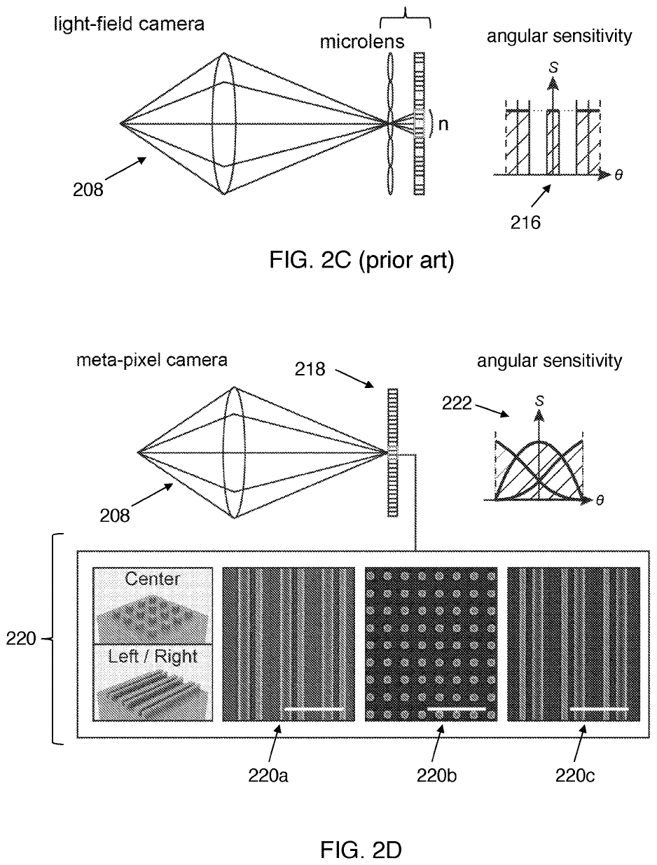

FIG. 2A shows scattering patterns of diffuse texture (202), specular texture (204), and their combination (206). FIGS. 2B-D are a comparison of previous and metapixel-based imaging systems: FIG. 2B shows a conventional camera, FIG. 2C shows a light-field camera, and FIG. 2D shows a metapixel camera. The schematic of each camera is presented together with the corresponding angular sensitivities. The detector array 210 in a conventional camera is not sensitive to the direction of incoming light and simply detects the total intensity at each point in an image, resulting in a flat angular sensitivity response 212. Using a microlens array and detector array combination 214, a light-field camera (FIG. 2C) separates the light rays at each position into a set of pixels that each sense the intensity in different directions, requiring a significant number of angular basis elements to capture continuous distributions. The result here is a discrete set of angular sensitivity bands, as shown by response 216.

In a metapixel camera (FIG. 2D), metapixels offer customized angular basis functions for efficient texture imaging integrated into the metapixel detector array 218. They feature designer high-index nanostructures at the top of otherwise conventional pixels. The schematics and SEMs of three types of fabricated metapixels (220a, 220b, 220c for left, center, right respectively) are shown as an inset 220. Here the scale bars are 1 μm. The resulting angular response as shown on 222 has three different responses that partially overlap with each other.

Under illumination, light is scattered by objects in a scene and collected by an imaging system. The scattered light carries a variety of information on a scene as differently modified by each visual attribute of objects. Among such attributes, surface texture shapes the scattering pattern of light from the surface of an object. For instance, a rough surface distributes the scattered light in a broad angular range (diffuse texture, e.g., 202 on FIG. 2A). On the other hand, a smooth and polished surface can produce a highly directional scattered beam (specular texture, e.g., 204 on FIG. 2A). Most surface textures display a combination of these two scattering mechanisms (e.g., 206 on FIG. 2A) that each incoherently contribute to the total scattering pattern.

Surface texture can be used as an effective visual cue to identify and classify imaged objects. To directly distinguish and image textures, we need an imaging system capable of discerning distinct angular distributions of the scattered light from each position in a scene. However, this cannot be achieved in a conventional imaging system whose image sensor is not sensitive to the direction of incoming light and simply detects the total intensity at each pixel location (FIG. 2B).

By placing a microlens array in front of the sensor, it is possible to separate the light rays at each position into a set of pixels such that each senses the intensity of light in different directions. Such a compound system, called a light-field camera (FIG. 2C), allows a single-shot imaging of a scene at discrete viewing angles. Still, it requires a significant number of angular basis elements to capture continuous distributions at the cost of spatial resolution.

To enable efficient texture imaging of an optical scene, we consider a new type of angle-sensitive pixel, called metapixels, that features designer high-index nanostructures at the top (FIG. 2D). As most image sensors are made from high-index semiconductors such as silicon, metapixels can be created simply by nanopatterning the top surface of otherwise conventional pixels. Due to their optical resonances, these nanostructures can display distinct interactions with light of different properties and render each pixel sensitive to specific properties of light. Inspired by the human color vision, we build three different types of angle-sensitive metapixels to construct angular basis functions for effective perception of texture. The human visual system can distinguish a large number of different colors (i.e., spectral distributions) using three types of photoreceptor cells whose sensitivity spectra not only peak at different wavelengths, but also overlap each other. Similarly, three types of metapixels are designed to be mostly sensitive to different incident angles of light. Their angular sensitivities are further tailored over a broad angular range of interest to facilitate perception of a wide range of textures. Moreover, this analogy between color and texture allows us to effectively visualize and highlight textures in an optical scene through quantitative color mapping.

FIG. 3A is a schematic illustration of a texture model. Here 302 shows a metapixel imaging system as described above, 304 is an exemplary angle dependent intensity from the illuminated scene, and 306 shows three angular responses that can act as a basis to account for arbitrary angle dependence. Here each texture is represented as a certain point in a three-dimensional texture space by using its tristimulus values as coordinates. FIG. 3B shows how a variety of textures can be discerned based on their positions in a texture space. Here 308 is the texture space, 310 is an exemplary angular locus and 312 is the Lambertian point. The effective visualization of textures can be enabled by quantitative color mapping according to their coordinates.

Before providing a detailed description of the metapixel design, we develop a mathematical model in which textures can be represented as tuples of numbers, in our example, three values (FIG. 3A). We call it a texture model by analogy with a color model in colorimetry. To illustrate this model, we consider a pixel sensor with three simple angular responses, each of which is either a Gaussian or sigmoid function with a small background. Their parameters are chosen so that three angular responses peak at the left-most (L), center (C), and right-most (R) angles respectively while reasonably overlapping each other. When light enters the sensor, these angular responses produce tristimulus values depending on the angular distribution of light:

$$L = \int {I}_{inc} ( θ ) \cdot {S}_{L} ( θ ) d θ , C = \int {I}_{inc} ( θ ) \cdot {S}_{C} ( θ ) d θ , R = \int {I}_{inc} ( θ ) \cdot {S}_{R} ( θ ) d θ ,$$

where I_{inc} is the intensity of incoming light per unit angle, and S₁ is the angular sensitivity of each response (i=L, C, R). Based on these tristimulus values, we can derive three normalized values, called texture coordinates, which capture the relative angular pattern of light independently from the total intensity:

$$l = \frac{L}{L + C + R} , c = \frac{C}{L + C + R} , r = \frac{R}{L + C + R} .$$

Using texture coordinates, each texture is represented as a certain point in a three-dimensional space, called a texture space (e.g., 308 on FIG. 3B). This enables us to discern a variety of textures based on their positions in a texture space. For instance, collimated beams at different angles (specular texture) and the Lambertian distribution (diffuse texture) correspond to a curved contour line (angular locus 310) and the center point (Lambertian point 312), respectively. Most textures including both specular and diffuse responses are placed in an area between these two representative cases. Furthermore, these textures can be effectively visualized by quantitative color mapping according to their coordinates. Note that different color mappings can be applied to enhance contrast between certain textures of interest.

FIG. 3C is a schematic of an angle-sensitive metapixel with different types of designer nanopatterns on the top surface. In this example, 320 is the silicon substrate, 322 is SiO₂, 324 is silicon, 326 is p-type silicon, 328 is the bottom electrode, 330 is p-type silicon, 332 is intrinsic silicon, 334 is n-type silicon, 336 is the top electrode, and 338 is an aperture in the top electrode in which the nanostructure patterning is performed. Practice of the invention does not depend critically on details of the detector structure.

Based on the texture model, we illustrate how metapixels can be created to obtain desired angular sensitivities for effective texture perception. FIG. 3C presents the schematic of an angle-sensitive metapixel used for experimental demonstration. We start from a 5-μm-thick c-Si pixel on Si-on-insulator (SOI) with a vertically defined p-i-n junction. Top and bottom electrodes are fabricated to selectively collect each type of photogenerated charge carriers. The effective pixel size is defined by a small opening 338 (100×100 μm²) in the top electrode 336 that also serves as an optical mask to reject light outside the area of interest. Note that this lateral size determines the spatial resolution of our metapixel imaging system later. For each type of metapixel, the top Si surface is differently nanopatterned to shape the angular sensitivities of the pixel as desired. The photograph and SEM of the fabricated three different types of metapixels are shown as insets. A planar pixel is also fabricated together with the metapixels as a reference.

Each of the Si nanopatterns is designed to tailor the angle-sensitive light absorption in each metapixel. It has recently been recognized that high-index semiconductor nanostructures can be utilized to form a new type of antireflection layer. Due to their local optical resonances, called Mie resonances, such high-index nanostructures can display strong and coherent light scattering that cancels out the reflection from a high-index semiconductor substrate. While several nanostructured antireflection layers have been reported previously, they have been typically engineered for broadband omnidirectional antireflection to maximize the overall light absorption in optoelectronic devices such as solar cells. Instead, by leveraging the ability of such resonances to control light waves, we create an angle-dependent nanostructured antireflection layer that selectively enhances light absorption at certain incident angles. This enables us to build high-efficiency metapixels with desired angular sensitivities, facilitating their operation over a wide range of light levels.

The nanopatterned top surfaces for C and L pixels are schematically shown in FIGS. 3D and 3E, respectively. The angular sensitivities of the metapixels are differently shaped with each of the designer nanopatterns via their angle-dependent antireflection. The simulated normal incidence field distribution of each type is shown in insets. FIG. 3F shows measured angle-dependent EQE (external quantum efficiency) of fabricated L (dashed line), C (solid line), and R (dotted line) metapixels. The EQE is spectrally averaged over the wavelength range of interest. The measured EQE of a planar (“planar Si” line) pixel is also shown as a reference.

The nanopatterned top surfaces of our angle-sensitive metapixels are schematically shown in FIGS. 3D-E. In the C pixel (FIG. 3D), a subwavelength array of Si nanoblocks is built on the Si active layer for a symmetric angular response based on reciprocity. The dimensions of the nanoblock array (p=320 nm, h=160 nm, and w=100 nm) are chosen such that the absorptance of the pixel peaks has a peak at normal incidence with a notable angular variation. On the other hand, a diffractive Si nanobeam array is constructed in the L (or R) pixel (FIG. 3E) for an asymmetric angular response peaking at an oblique incident angle. The bimodal size distribution and alternating interparticle distances of the nanobeam array (p=700 nm, h=160 nm, w₁=155 nm, w₂=80 nm, and d=255 nm) are engineered to diffract a small amount of normally incident light preferably into one of the first-order channels in the air. This leads to different total diffraction efficiencies into the air and thus total absorptances in the pixel at positive and negative incident angles, especially where one of these diffraction channels closes. The simulated magnetic field distribution of each designer nanopattern is shown as an inset, respectively, in FIGS. 3D-E. Note that all these nanopatterns are designed with the same height to facilitate their incorporation into an existing image sensor with a single nanopatterning step.

FIG. 3F shows the measured external quantum efficiencies (EQEs) of the fabricated pixels at different incident angles. Compared to the planar one, the metapixels display higher EQEs over the broad angular range of interest, resulting from their nanostructured antireflection surfaces based on relatively low-Q Mie resonances. The enhancement in EQEs for each metapixel follows distinct angular dependence that resembles the angular basis elements used in our texture model (FIG. 3A). Due to their overall high EQEs, each of the metapixels senses the total light intensity with a high efficiency, similar to conventional pixels. At the same time, their angle-sensitive differential responses are leveraged to effectively perceive textures based on a texture space. By using a linear transformation, effective angular response functions are further synthesized from the measured EQE curves to construct a texture space in which certain textures of interest can be highlighted.

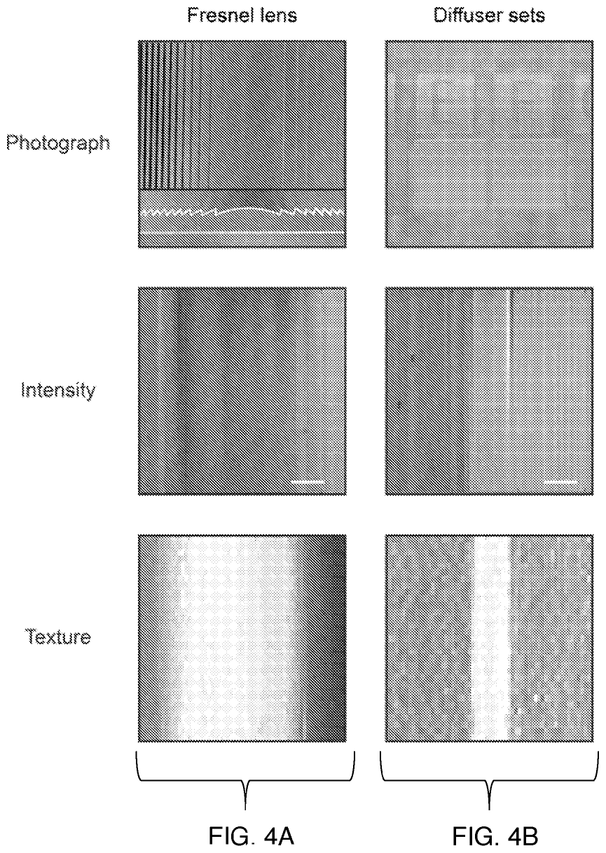

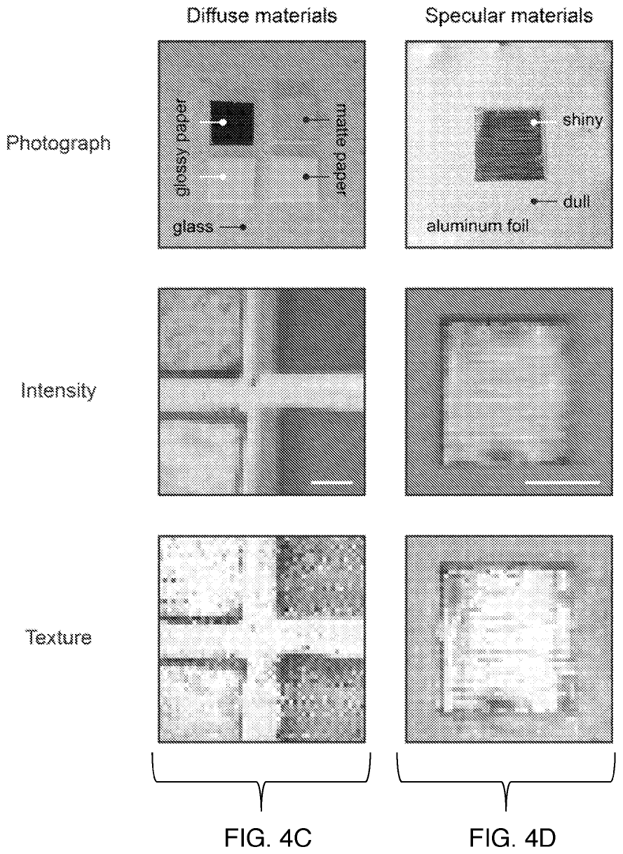

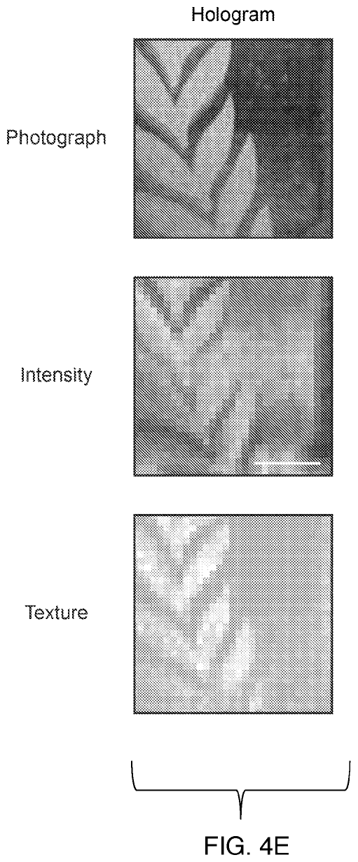

FIGS. 4A-4E shows texture images of various optical scenes materials: a cylindrical Fresnel lens (FIG. 4A), a holographic diffuser set (FIG. 4B), practical material libraries (FIGS. 4C-D), and a security hologram (FIG. 4E). The objects for FIGS. 4A-B are transparent and the objects for FIGS. 4C-E are opaque. For each scene, a conventional photograph and the intensity image captured by the C pixel are also shown as references.

To demonstrate the imaging capabilities, we now capture images of various optical scenes with our angle-sensitive metapixels (FIG. 4A-F). The images are acquired by raster-scanning the fabricated metapixels in an imaging system with a roughly collimated incoherent external light source. By using a simple linear transformation, a color-coded texture image is synthesized in a pixel-by-pixel fashion from a set of intensity images captured with each of the metapixels. For each scene, the texture image is presented together with the intensity image from the C pixel as a reference. First, we consider two types of optical components, a Fresnel lens and an optical diffuser set, that each can produce specular or diffuse scattering patterns (FIGS. 4A-B). Since these optical elements are transparent materials, the intensity images display no notable spatial variations associated with their optical functions. On the contrary, the spatially dependent scattering properties are clearly revealed in the texture images. For the cylindrical Fresnel lens, continuously varying local diffraction angles are translated into continuous variation in texture color closely along the angular locus in the texture diagram, indicating the capability to perceive subtle differences in textures. For the optical diffuser set, linear diffuser patches with different diffusion angles are represented by discrete texture colors around the vertical center line passing through the Lambertian point in the texture diagram.

Next, we examine optical scenes that are composed of practical materials with different textures: practical material libraries (FIGS. 4C-D). A diffuse material library contains four pieces of papers on glass in combination with two different colors and finishes. On the other hand, a specular material library consists of the same aluminum foil, but with the opposite sides and different surface roughness. Compared to the conventional photographs and the intensity images, the texture images from the metapixels demonstrate unique and effective visual perception of the scenes based on texture, which is complementary to that based on intensity or color. As local texture values are quantitatively measured, these texture images can be further utilized with appropriate scattering models to facilitate physically based rendering in computer graphics. Also, we explore an example of optical scenes that contain materials with engineered textures: a security hologram (FIG. 4E). In a security hologram, the scattering patterns are specifically shaped to generate certain visual effects depending on viewing angles. These security features can be highlighted with different colors in the texture image, enabling single-shot and quantitative authentication. Moreover, our metapixels can be customized to recognize and authenticate specific security holograms with higher fidelity.

1. An angle-sensitive optical imaging array comprising:
an array of pixel detection elements, wherein each pixel detection element includes
i) an optical detector, and
ii) an optical nanostructure disposed on or over the optical detector and configured such that the pixel detection element is angle-sensitive;
wherein the pixel detection elements comprise two or more classes of pixel detection elements, each class of pixel detection elements including two or more pixel detection elements;
wherein pixel detection elements in the same class have the same angle-sensitive response;
wherein pixel detection elements in different classes have different angle-sensitive responses;
wherein the different angle-sensitive responses have response vs. angle curves that overlap.

2. The angle-sensitive optical imaging array of claim 1, wherein the two or more classes of pixel detection elements are three classes of pixel detection elements, and wherein a false coloring having three primary colors is used to display texture as color.

3. The angle-sensitive optical imaging array of claim 2, wherein the three classes of pixel detection elements are configured to distinguish three different 1-D incidences.

4. The angle-sensitive optical imaging array of claim 1, wherein the two or more classes of pixel detection elements are four classes of pixel detection elements, and wherein the four classes of pixel detection elements are configured to distinguish four different 2-D incidences.

5. The angle-sensitive optical imaging array of claim 1, wherein the two or more classes of pixel detection elements are three or more classes of pixel detection elements configured to distinguish three or more different 1-D or 2-D incidences.

6. The angle-sensitive optical imaging array of claim 1, wherein the optical nanostructure is an optical metasurface.

7. The angle-sensitive optical imaging array of claim 6, wherein the optical metasurface is disposed over the optical detector.

8. The angle-sensitive optical imaging array of claim 6, wherein the optical metasurface is integrated with the optical detector.

9. The angle-sensitive optical imaging array of claim 1, wherein the optical nanostructure comprises one or more nano-scale features of the optical detector.

10. The angle-sensitive optical imaging array of claim 1, wherein at least one of the different angle-sensitive responses is configured to act as a matched filter for a texture of interest.
